(19) United States
(12) Patent Application Publication
(10) Pub. No.: US 2024/0204478 A1
(43) Pub. Date: Jun. 20, 2024

(54) DRIVER CIRCUIT, CORRESPONDING LASER-DRIVING DEVICE, LASER LIGHTING MODULE, LIDAR APPARATUS AND METHODS OF OPERATION

(71) Applicants: STMicroelectronics (Rousset) SAS, Rousset (FR); STMicroelectronis S.r.l., Agrate Brianza (MB) (IT)

(72) Inventors: Romeo Letor, Mascalucia (CT) (IT); Alfio Russo, Acireale (CT) (IT); Nadia Lecci, Tremestieri Etneo (CT) (IT); Antonio Filippo Massimo Pizzardi, Misterbianco (IT); Antoine Pavlin, Puyricard (FR); Vanni Poletto, Milano (IT); Marco Brera, Milano (IT); Simone Bianchi, Alessandria (IT)

(21) Appl. No.: 18/533,585

(22) Filed: Dec. 8, 2023

(30) Foreign Application Priority Data
Dec. 14, 2022 (IT) 102022000025605

(51) Int. Cl. H01S 5/026; G01S 7/481; H01S 5/02326; H01S 5/40

(52) U.S. Cl. CPC H01S 5/0261; G01S 7/4814; H01S 5/02326; H01S 5/4025

(57) ABSTRACT

In a driver circuit couplable to laser diodes, a semiconductor body has a first surface. First and second control switches have drains coupled to a drain metallization, which is couplable to a power supply line, and sources coupled to respective first and second source metallizations, which are couplable to cathode terminals of the laser diodes and a reference node. A plurality of high-side switches have drains coupled to the drain metallization and sources coupled to third source metallizations, each of which is coupled to a respective drive output node for driving an anode terminal of a respective laser diode. The drain, first, second and third source metallizations face the first surface of the semiconductor body, which faces the laser diodes. The second and third source metallizations are aligned with one another and are superimposed to the respective source terminals of the second control switch and high-side switches.

### CROSS-REFERENCE TO RELATED APPLICATIONS

This application claims the benefit of Italian Patent Application No. 102022000025605, filed on Dec. 14, 2022, entitled “Driver circuit, corresponding laser-driving device, laser lighting module, LIDAR apparatus and methods of operation” which application is hereby incorporated herein by reference to the maximum extent allowable by law.

### TECHNICAL FIELD

The present disclosure relates to a driver circuit for LIDAR (Light Detection And Ranging or Laser Imaging Detection And Ranging) applications. In particular, it relates to a driver circuit couplable to a control circuit and to a plurality of laser diodes for biasing them. In addition, the present disclosure relates to a laser-driving device (e.g., implemented as a System-in-Package, SiP) including the driver circuit and the control circuit, to a lighting module including the laser-driving device and the laser diodes, to a LIDAR apparatus including the lighting module, and to methods of operating the laser-driving device and the laser lighting module.

### BACKGROUND

Thanks to their 3D sensing capacity and to the ability to function in the dark and in unfavorable meteorological conditions, LIDAR systems are increasingly used in the automotive sector, in possible combination with video cameras and radar systems, for environmental mapping and for other safety applications, such as emergency braking, detection of pedestrians and collision avoidance.

Very short high-current pulses (such as current pulses that have an intensity in the range of tens of amps with rise and fall times in the (sub)nanosecond time range, for example, of the order of 100 ps) are desirable for laser diodes for LIDAR systems used for measuring the distances with time-of-flight (ToF) measurements techniques with medium-to-short distance values (e.g., distances of less than approximately 100 m with resolution of measurement of about ±15 cm).

Arrays of laser diodes including laser diodes activated in sequence or in parallel are also used for improving the signal-to-noise (S/N) ratio of the return signal received. Multi-channel drivers offer the possibility of selecting the diode (diodes) to be activated with a short current pulse of high intensity.

Circuits, devices, lighting modules and apparatuses for use in LIDAR applications are known, for instance, from references US 2022/0013982 A1 and US 2022/0014187 A1, which are assigned to the same Applicants of the instant application. Additionally, references US 2022/0013984 A1 and US 2021/0218223 A1, which are also assigned to the same Applicants of the instant application, disclose implementation details of such circuits and devices. All the patent applications listed above are hereby incorporated herein by reference in their entireties, also for the purpose of possibly seeking protection for one or more of the features disclosed therein, which may contribute to solve the technical problem solved by one or more embodiments of the present disclosure.

However, existing LIDAR systems present non-negligible parasitic inductances (e.g., higher than 1 nH) and/or capacitances, in particular on account of the use of the arrays of laser diodes, which cause degraded electrical performance of the latter. For instance, known solutions may be limited by a current rating in the range of about 20 A, mainly due to the maximum current capability of the laser-selecting switches and the maximum power dissipation of the switch that is used to drive a resonant current wave. Attaining a higher current rating by increasing the chip size would result in: lengthier connections to ground (which result in increased stray inductances in the commutation loop), increased output capacitance of the switch that drives the resonant current wave, deteriorated switching time and increased current overshoot due to resonance in the commutation loop with a period in the nanosecond range (which result in a poor current control in the nanosecond range).

Reduction of the parasitic inductances and/or capacitances is therefore a desirable feature in the implementation of a driver circuit for laser diodes designed for high current ratings.

### SUMMARY

An object of one or more embodiments is to contribute in providing driver circuits having an improved topology and/or chip layout that results in reduced parasitic inductances and/or capacitances.

According to one or more embodiments, such an object can be achieved by a driver circuit having the features set forth in the claims that follow.

One or more embodiments may relate to a corresponding laser-driving device including a driver circuit and a control circuit.

One or more embodiments may relate to a corresponding laser lighting module including a laser-driving device, one or more laser diodes and a power supply arrangement.

One or more embodiments may relate to a corresponding LIDAR apparatus including a laser lighting module.

One or more embodiments may relate to corresponding methods of operating the laser-driving device and the laser lighting module.

The claims are an integral part of the technical teaching provided herein in respect of the embodiments.

According to a first aspect of the present description, a driver circuit is couplable to a plurality of laser diodes. The driver circuit includes a semiconductor body having a first surface. The driver circuit includes a first control switch (e.g., transistor) having a drain terminal electrically coupled to a drain metallization and having a source terminal electrically coupled to a first source metallization. The drain metallization is configured to be electrically coupled to a power supply line and the first source metallization is configured to be coupled to cathode terminals of the laser diodes and to a reference node. The driver circuit includes a second control switch (e.g., transistor) having a drain terminal electrically coupled to the drain metallization and having a source terminal electrically coupled to a second source metallization. The second source metallization is configured to be coupled to the cathode terminals of the laser diodes and to a reference node. The driver circuit includes a plurality of high-side switches (e.g., transistors), each high-side switch having a respective drain terminal electrically coupled to the drain metallization and having a respective source terminal electrically coupled to a respective third source metallization. Each third source metallization is coupled to a respective drive output node for driving an anode terminal of a respective laser diode of the plurality of laser diodes. The drain metallization, the first source metallization, the second source metallization and the third source metallizations face the first surface of the semiconductor body, which is also configured to face the laser diodes. The second source metallization and the third source metallizations are aligned with one another in a direction of alignment and are superimposed, orthogonally to the direction of alignment, to the respective source terminals of the second control switch and of the high-side switches.

One or more embodiments may thus provide a driver circuit for laser diodes having improved topology and layout that reduce parasitic inductances.

According to another aspect of the present description, a laser-driving device (e.g., in the form of a System-in-Package, SiP) includes a driver circuit according to one or more embodiments and a control circuit for driving the first control switch, the second control switch and the high-side switches to cyclically generate pulses for activating the laser diodes. The control circuit is configured to:
sense a voltage across a capacitor of an external resonant circuit;
in response to the sensed voltage reaching a first threshold value, close the first control switch and the second control switch, thereby enabling the resonant circuit to oscillate with a current (e.g., increasing current) that flows in an inductor of the resonant circuit and is split between the first control switch and the second control switch;
in response to the current flowing in the inductor of the resonant circuit reaching a second threshold value, open the first control switch and keep closed the second control switch for a first time interval, whereby the current flows entirely through the second control switch;
in response to expiration of the first time interval, open the second control switch and close a first selected high-side switch for a second time interval, whereby the current flows entirely through the first selected high-side switch and is output via a respective first drive output node; and
in response to expiration of the second time interval, open the first selected high-side switch.

According to another aspect of the present description, a laser lighting module includes a laser-driving device according to one or more embodiments and a resonant circuit including an inductor and a capacitor having an intermediate node between them. The resonant circuit is coupled between the power supply line and the reference node. The laser lighting module further includes a charging circuitry coupled between a supply node and the intermediate node of the resonant circuit for charging the capacitor of the resonant circuit, and a plurality of laser diodes. Each of the laser diodes has an anode terminal electrically coupled to a respective one of the drive output nodes and a cathode terminal electrically coupled to the reference node.

According to another aspect of the present description, a LIDAR apparatus includes a laser light emitter path including a LIDAR mirror module and a laser lighting module according to one or more embodiments, a laser light receiver path including a photodiode module and a receiver circuit coupled to the photodiode module, and a controller circuit. The controller circuit is configured to emit driving signals for the LIDAR mirror module and the laser lighting module, and receive raw data from the receiver circuit coupled to the photodiode module.

According to another aspect of the present description, a method of operating a laser- driving device according to one or more embodiments includes:
sensing a voltage across a capacitor of an external resonant circuit;
in response to the sensed voltage reaching a first threshold value, closing the first control switch and the second control switch, thereby enabling the resonant circuit to oscillate with a current that flows in an inductor of the resonant circuit and is split between the first control switch and the second control switch;
in response to the current flowing in the inductor of the resonant circuit reaching a second threshold value, opening the first control switch and keeping closed the second control switch for a first time interval, whereby the current flows entirely through the second control switch;
in response to expiration of the first time interval, opening the second control switch and closing a first selected high-side switch for a second time interval, whereby the current flows entirely through the first selected high-side switch and is output via a respective first drive output node; and
in response to expiration of the second time interval, opening the first selected high-side switch.

According to another aspect of the present description, a method of operating a laser lighting module according to one or more embodiments includes:
initially opening the first control switch and the second control switch to charge the capacitor via the charging circuitry, and
operating the laser-driving device according to the method of one or more embodiments.

### BRIEF DESCRIPTION OF THE DRAWINGS

One or more embodiments will now be described, by way of example only, with reference to the annexed figures, wherein:

FIG. 1 is a circuit diagram exemplary of a laser lighting module that may be included in a LIDAR apparatus according to one or more embodiments of the present description;

FIGS. 2, 3 and 4 are waveforms exemplary of the resonant current flowing through a resonant circuit according to one or more embodiments of the present description;

FIG. 5 is a circuit diagram exemplary of certain components of a laser lighting module according to one or more embodiments of the present description;

FIGS. 6 and 7 are circuit layout diagrams exemplary of the chip layout of a driver circuit according to one or more embodiments of the present description;

FIG. 8 is a time diagram exemplary of the switching behavior of a laser lighting module according to one or more embodiments of the present description; and

FIG. 9 is a circuit block diagram exemplary of a LIDAR apparatus, possibly mounted on a vehicle, according to one or more embodiments of the present description.

### DETAILED DESCRIPTION OF ILLUSTRATIVE EMBODIMENTS

In the ensuing description, one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is included in at least one embodiment. Hence, phrases such as “in an embodiment” or “in one embodiment” that may be present in one or more points of the present description do not necessarily refer to one and the same embodiment. Moreover, particular configurations, structures, or characteristics may be combined in any adequate way in one or more embodiments.

The headings/references used herein are provided merely for convenience and hence do not define the extent of protection or the scope of the embodiments.

Throughout the figures annexed herein, unless the context indicates otherwise, like parts or elements are indicated with like references/numerals and a corresponding description will not be repeated for the sake of brevity.

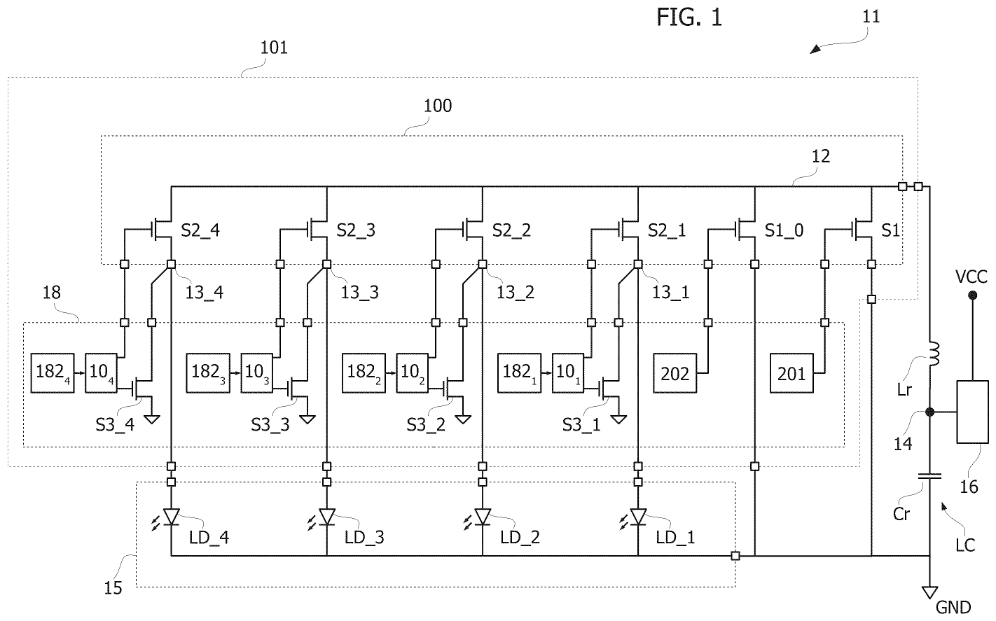

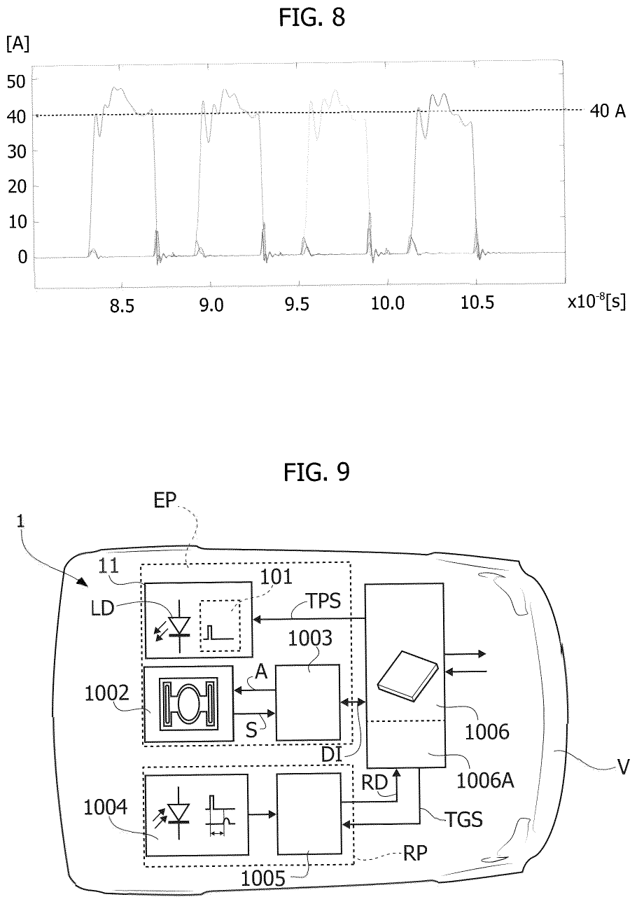

FIG. 1 is a circuit diagram exemplary of a laser lighting module 11 that may be included in a LIDAR apparatus 1 (exemplified in FIG. 9), according to an embodiment of the present disclosure.

The laser lighting module 11 includes a laser-driving device and a plurality of laser diodes. For instance, in FIG. 1 four laser diodes are illustrated, which are arranged in an array and are designated by the reference symbols LD_1, LD_2, LD_3, LD_4 (generally LD_j, where j=1, 2, . . . , n and n is the number of laser diodes that form the array; by way of non-limiting example, thus, n=4). The laser diodes LD_j are configured to be selectively activated (e.g., in a pulsed way) by respective half-bridge circuits. In particular, each half-bridge circuit includes a pair of electronic switches such as field-effect transistors and, for example, HEMT (High

Electron Mobility Transistor) devices and/or MOSFET (Metal-Oxide-Semiconductor Field-Effect Transistor) devices. In detail, each half-bridge circuit includes a high-side switch S2_j (e.g., S2_1, S2_2, S2_3, S2_4 in the example of FIG. 1) coupled between a power supply line 12 common to all the half-bridge circuits and a respective driving node 13_j (e.g., 13_1, 13_2, 13_3, 13_4 in the example of FIG. 1), and a low-side switch S3_j (e.g., S3_1, S3_2, S3_3, S3_4 in the example of FIG. 1) coupled between the respective driving node 13_j and a reference line (e.g., a ground GND, referred to in what follows as reference node GND) common to all the half-bridge circuits. The cathode terminal of each laser diode LD_j is coupled to the reference node GND, and the anode terminal of each laser diode LD_j is coupled to the driving node 13_j of the respective half-bridge circuit (e.g., the laser diodes LD_j are arranged in a common-cathode configuration). Thus, a first half-bridge S2_1, S3_1 drives a first laser diode LD_1, a second half-bridge S2_2, S3_2 drives a second laser diode LD_2, a third half-bridge S2_3, S3_3 drives a third laser diode LD_3, and a fourth half-bridge S2_4, S3_4 drives a fourth laser diode LD_4. The half-bridge circuits are driven by respective driving circuits 10ⱼ coupled to the control terminals (e.g., gate terminals) of the high-side switches S2_j and low-side switches S3_j.

A resonant tank (or circuit) LC that includes an inductor Lr and a capacitor Cr connected in series is coupled between the power supply line 12 and the reference node GND. The inductor Lr is arranged between the power supply line 12 and an intermediate node 14 of the resonant circuit LC, and the capacitor Cr is arranged between the intermediate node 14 and the reference node GND. The intermediate node 14 is coupled to a charge circuit (also referred to in what follows as regulator) 16, of a known type, which receives a supply voltage VCC.

A first control switch S1, such as a gallium nitride (GaN) field-effect transistor (for example, a GaN HEMT), is coupled between the power supply line 12 and the reference node GND. A second control switch S1_0, such as a gallium nitride (GaN) field-effect transistor (for example, a GaN HEMT), is also coupled between the power supply line 12 and the reference node GND. The control switches S1, S1_0 and the half-bridge switches S2_j, S3_j are driven as a function of enable signals supplied, as discussed hereinafter, by a control circuit designated as a whole by reference numeral 18, which includes the half-bridge driving circuits 10ⱼ . It may be considered that the control circuit 18 includes: the half-bridge driving circuits 10ⱼ; respective control circuits 182ⱼ for the half-bridge driving circuits 10ⱼ configured to send to the half-bridge driving circuits 10ⱼ respective enable signals Ton_S2_j to enable supply of energy to (and therefore emission of light from) the respective laser diodes LD_j; a control circuit 201 configured to control the first control switch S1 (e.g., driving its control terminal, i.e., a gate terminal in the case of a field-effect transistor); and a control circuit 202 configured to control the second control switch S1_0 (e.g., driving its control terminal, i.e., a gate terminal in the case of a field-effect transistor).

As mentioned earlier, the control circuits 182ⱼ, 201 and 202, as well as the half-bridge driving circuits 10ⱼ, are represented as distinct entities purely for simplicity of description and understanding. These control and driving circuits may be integrated in a single control unit 18, which may also incorporate the low-side switches S3_j. In fact, it will be understood that the components of a laser lighting module 11 as exemplified in FIG. 1 may be arranged as follows:
the high-side switches S2_j and the control switches S1, S1_0, which may all be implemented as GaN power transistors (e.g., configured to operate in the power range of 100 W), may be (monolithically) integrated in a GaN integrated circuit (IC) 100, which may per se form an embodiment according to an aspect of the present disclosure (e.g., a driver circuit 100);
the low-side switches S3_j and the control and driving circuits 10ⱼ, 182ⱼ, 201 and 202, which may all be implemented in a conventional silicon-based CMOS technology (e.g., configured to operate at low power), may be integrated in a CMOS integrated circuit (IC) 18; the GaN circuit 100 and the CMOS circuit 18 may be incorporated in a same package (e.g., as a System-in-Package, SiP, or as a single solid body of semiconductor material) and form an embodiment according to another aspect of the present disclosure (e.g., a laser-driving device 101);
the laser diodes LD_j may be provided as discrete components or incorporated in an integrated circuit 15, and they may be coupled (e.g., by an end user such as a system integrator) to the laser-driving device 101 (e.g., being mounted on a printed circuit board, PCB, or being housed in a cavity of the solid body of semiconductor material) together with the resonant circuit LC and the regulator 16 to form an embodiment according to another aspect of the present disclosure (e.g., a laser lighting module 11 that may be used as a transmitter stage in a LIDAR apparatus 1 for distance measurement by time-of-flight, ToF, methods).

As described more comprehensively in the following, the control circuit 18 enables co-ordination of operation of the control switches S1 and S1_0 with operation of the high-side switches S2_j and of the low-side switches S3_j in order to generate (ultra)short current pulses (e.g., having rise times and fall times in the order of the (sub)nanosecond time range and, for example, in the order of 100 ps), with high di/dt (e.g., higher than approximately 80 nA/ns) and high magnitude (e.g., reaching 40 A or more), which are switched on the laser diodes LD_j to obtain individual activation (e.g., sequential activation with a delay in the order of 1 ns) and selective emission of light.

In particular, the control switches S1 and S1_0 are connected in parallel to all the light-emission channels, as well as to the resonant circuit LC, and are thus configured to control energy supply from the regulator 16 to the resonant circuit LC, thereby defining the energy content and the peak current of the pulses of the laser diodes LD_j when activated. The regulator 16 can be implemented in a manner known per se so as to charge the capacitor Cr in the resonant circuit LC to a voltage adequate for obtaining a peak current in the resonant circuit LC equal to or higher than a desired pulse current of the laser diodes LD_j.

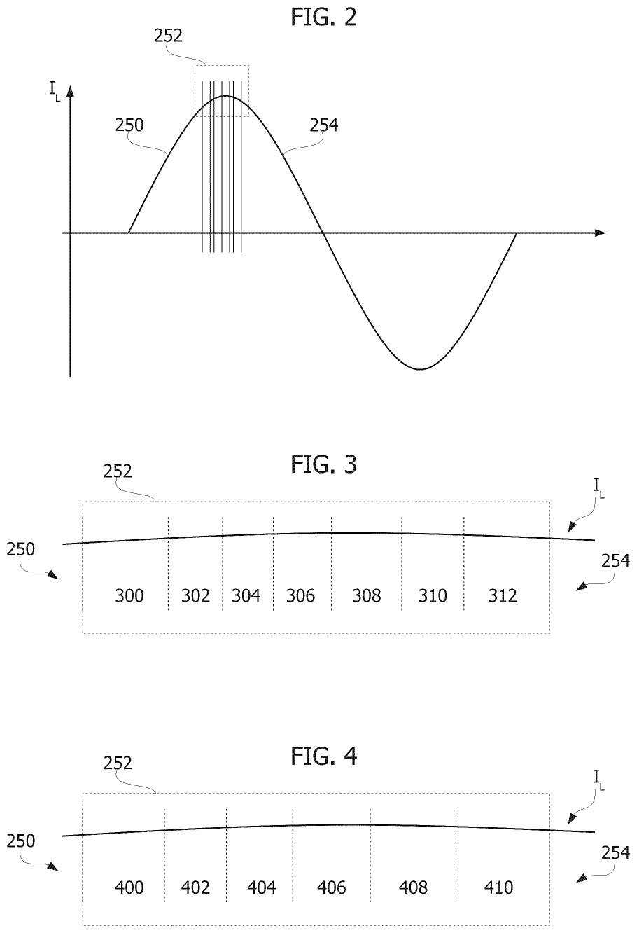

There now follows a description of a method of operating the laser lighting module 11. Such a method may be better understood with reference to FIGS. 2, 3 and 4, where FIG. 2 is a waveform of the resonant current I_{L} flowing through the resonant circuit LC, FIG. 3 is an enlarged view of a portion of the waveform of FIG. 2 during an independent laser activation phase, and FIG. 4 is an enlarged view of a portion of the waveform of FIG. 2 during a sequential laser activation phase.

In particular, the high-side and low-side switches S2_j and S3_j are driven by the control circuit 18 in half-bridge configuration so that: when the high-side switch S2_j is on (i.e., closed, conductive), the corresponding low-side switch S3_j is off (open, non-conductive), and the corresponding laser diode LD_j can be activated by injecting current in the latter through the respective light-emission channel; and, when the high-side switch S2_j is off, the low-side switch S3_j is on, thus coupling the respective driving node 13_j to the reference node GND and countering undesired spurious currents that could flow through the laser diode LD_j. It will otherwise be noted that provision of the low-side switches S3_j may not be essential for the operation of the laser lighting module 11, so that one or more embodiments may not be provided with low-side switches S3_j and the corresponding driving circuitry.

In greater detail, the control switches S1 and S1_0 are initially off, so that the capacitor Cr is charged by the regulator 16 to a voltage value (e.g., comprised between approximately 10 V and approximately 20 V) that is adequate for obtaining a desired current in the resonant circuit LC (e.g., comprised between approximately 20 A and approximately 60 A).

The control switches S1 and S1_0 are then both switched on, so that the resonant circuit LC starts to oscillate and the current I_{L} increases in the inductor Lr (see, e.g., the waveform portion 250 in FIG. 2), with the resonant current being distributed (e.g., shared, split) between switches S1 and S1_0. In response to the fact that the current I_{L} of the resonant circuit LC reaches a threshold, a laser firing phase starts (see, e.g., the waveform portion 252 in FIG. 2, which is enlarged in FIGS. 3 and 4).

If the laser channels are driven in an independent manner (i.e., with the possibility of activating the laser diodes LD_j in any order during the firing phase 252), as exemplified in FIG. 3, during an initial portion 300 of the firing phase 252 (e.g., 1 ns before the expected laser firing) the control switch S1 is turned off while the control switch S1_0 remains on, so that the resonant current I_{L} is forced to flow through switch S1_0 only. The control switch S1 will remain off for the entire duration of the firing phase 252. During a subsequent portion 302 of the firing phase 252, the control switch S1_0 is also turned off while one of the high-side switches S2_j is turned on, so that the resonant current I_{L} flowing through the inductor Lr is deviated in the respective laser diode LD_j and light emission takes place for the desired pulse duration (e.g., 1 ns). During a subsequent portion 304 of the firing phase 252, the control switch S1_0 is again turned on while the high-side switch S2_j previously activated is turned off, so that the resonant current I_{L} is again forced to flow through switch S1_0 only. Portions 306 and 310 of the firing phase 252 substantially reproduce the behavior of portion 302 (i.e., switch S1_0 is turned off and one of the high-side switches S2_j is turned on), while portions 308 and 312 of the firing phase 252 substantially reproduce the behavior of portions 300 and 304 (i.e., switch S1_0 is turned on and all the high-side switches S2_j are turned off). At the end of the laser firing phase 252, both control switches S1 and S1_0 are switched on again (see, e.g., the waveform portion 254 in FIG. 2).

According to a different driving scheme, if the laser channels are driven in a sequential manner (i.e., activating all the laser diodes LD_j sequentially), as exemplified in FIG. 4, during an initial portion 400 of the firing phase 252 (e.g., 1 ns before the expected laser firing) the control switch S1 is turned off while the control switch S1_0 remains on, so that the resonant current I_{L} is forced to flow through switch S1_0 only. The control switch S1 will remain off for the entire duration of the firing phase 252. During a subsequent portion 402 of the firing phase 252, the control switch S1_0 is also turned off while the high-side switch S2_1 is turned on, so that the resonant current I_{L} flowing through the inductor Lr is deviated in the laser diode LD_1 and light emission takes place for the desired pulse duration (e.g., 1 ns). During a subsequent portion 404 of the firing phase 252, the control switch S1_0 remains off, the high-side switch S2_1 is turned off, and the subsequent high-side switch S2_2 is turned on, so that the resonant current I_{L} is deviated in the laser diode LD_2. During a subsequent portion 406 of the firing phase 252, the control switch S1_0 remains off, the high-side switch S2_2 is turned off, and the subsequent high-side switch S2_3 is turned on, so that the resonant current I_{L} is deviated in the laser diode LD_3. During a subsequent portion 408 of the firing phase 252, the control switch S1_0 remains off, the high-side switch S2_3 is turned off, and the subsequent high-side switch S2_4 is turned on, so that the resonant current I_{L} is deviated in the laser diode LD_4. During a subsequent portion 410 of the firing phase 252, the control switch S1_0 is again turned on while the high-side switch S2_4 (as well as the other high-side switches) is turned off, so that the resonant current I_{L} is again forced to flow through switch S1_0 only. At the end of the laser firing phase 252, both control switches S1 and S1_0 are switched on again (see, e.g., the waveform portion 254 in FIG. 2).

Therefore, in various embodiments, laser firing is obtained by switching the control switch S1_0 off and on so that when switch S1_0 is off, one of the high-side switches S2_j is on and vice-versa. Switch S1 instead remains off for the entire duration of the laser firing phase. The entirety of the resonant current stored in the resonant circuit LC (Lr, Cr) is transferred to switch S1_0 before the laser firing phase. Switch S1_0 is switched on and off to transfer the current I_{L} in the laser diodes. Switch S1 is switched on again at the end of the laser firing phase.

In various embodiments, the control switches S1 and S1_0 may be dimensioned differently so as to improve the performance of the driver circuit 100, insofar as they play a different function in the operation of the laser lighting module 11. In particular, switch S1 may be larger than switch S1_0. Therefore, switch S1 may have an on-state resistance (R_{DS,on}) lower than the on-state resistance of switch S1_0, at the price of a higher output capacitance (e.g., switch S1 having an output capacitance being about twice the output capacitance of switch S1_0, such as 180 pF for switch S1 and 90 pF for switch S1_0). By doing so, one or more embodiments facilitate reducing power dissipation, switching time and current overshoot. In fact, the on-state resistance of switch S1 may be dimensioned to minimize the power dissipation while driving the resonant current I_{L} in the inductor Lr (power=R_{DS,ON}*I_{RMS}), insofar as this dimensioning does not affect the switching time of the laser diodes since fast switching is performed by the other control switch S1_0. The power dissipation in switch S1_0 may also be reduced since its short conduction time (e.g., ns range) minimizes the RMS current flowing through switch S1_0. Thus, the switching performance during current transfer to the laser diodes LD_j is improved insofar as the commutation is driven (only) by switch S1_0 that has an output capacitance smaller than switch S1. Such a smaller output capacitance, combined with a reduction of stray inductances obtained by shortening the conduction path of the commutation loop, minimizes the resonant period and the current overshoot during commutation of switch S1_0.

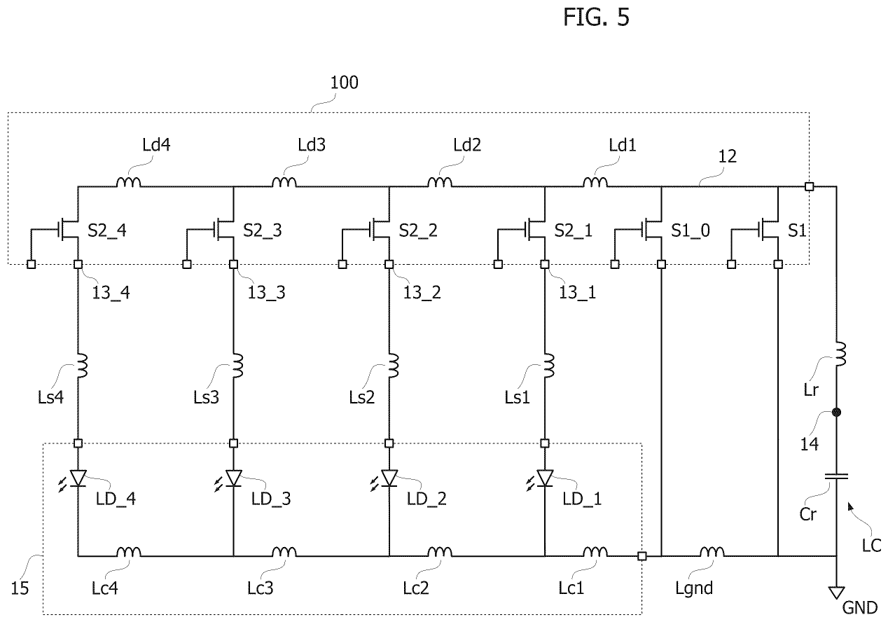

FIG. 5 is a circuit diagram that illustrates certain components of the laser lighting module 11. In particular, there are shown the driver circuit 100, the laser diodes LD_j and the resonant circuit coupled to each other, and some parasitic inductances that may be present. For instance, parasitic inductances Ld1, Ld2, Ld3, Ld4 (e.g., having an inductance of about 50 pH each) may be present at the drain terminals of the high-side GaN transistors S2_1, S2_2, S2_3, S2_4, respectively; in particular, inductance Ld1 may be located between the drain terminals of transistors S2_1 and S1_0; inductance Ld2 may be located between the drain terminals of transistors S2_2 and S2_1; inductance Ld3 may be located between the drain terminals of transistors S2_3 and S2_2; and inductance Ld4 may be located between the drain terminals of transistors S2_4 and S2_3. Additionally, parasitic inductances Ls1, Ls2, Ls3, Ls4 (e.g., having an inductance of about 25 pH each) may be present at the source terminals of the high-side GaN transistors S2_1, S2_2, S2_3, S2_4, respectively; in particular, inductance Ls1 may be located between the source terminal of transistor S2_1 and the anode terminal of laser diode LD_1; inductance Ls2 may be located between the source terminal of transistor S2_2 and the anode terminal of laser diode LD_2; inductance Ls3 may be located between the source terminal of transistor S2_3 and the anode terminal of laser diode LD_3; inductance Ls4 may be located between the source terminal of transistor S2_4 and the anode terminal of laser diode LD_4. Additionally, parasitic inductances Lc1 (e.g., having an inductance of about 100 pH) and Lc2, Lc3, Lc4 (e.g., having an inductance of about 50 pH each) may be present at the cathode terminals of the laser diodes LD_1, LD_2, LD_3, LD_4, respectively; in particular, inductance Lc1 may be located between the cathode terminal of laser diode S2_1 and the source terminal of GaN transistor S1_0; inductance Lc2 may be located between the cathode terminals of laser diodes LD_2 and LD_1; inductance Lc3 may be located between the cathode terminals of laser diodes LD_3 and LD_2; inductance Lc4 may be located between the cathode terminals of laser diodes LD_4 and LD_3. Additionally, parasitic inductance Lgnd (e.g., having an inductance of about 1 nH) may be located between the source terminals of transistors S1_0 and S1. Additionally, transistor S1_0 may have an output capacitance of about 90 pF and transistor S1 may have an output capacitance of about 180 pF.

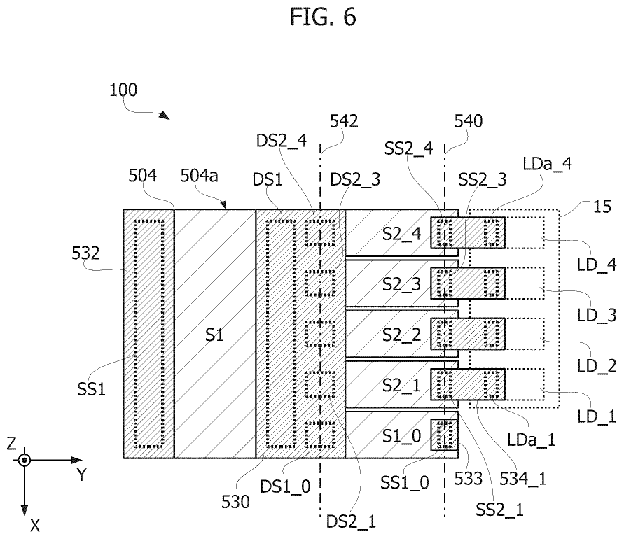

FIGS. 6 and 7 are layout diagrams that exemplify the chip layout (e.g., in a top view) of a GaN integrated circuit 100 according to one or more embodiments.

The integrated circuit 100 includes a semiconductor body 504 (of semiconductor material such as gallium nitride, GaN). The semiconductor body 504 has a first (e.g., top or upper) surface 504a and a second (e.g., bottom or lower) surface 504b parallel to plane XY and opposite to one another along an axis Z (e.g., axis Z being orthogonal to the plane of the sheet of FIGS. 6 and 7, which is plane XY). The semiconductor body 504 includes the control switches S1 and S1_0, as well as the high-side switches S2_j (in this example, four switches S2_1, S2_2, S2_3 and S2_4). For the sake of easy of illustration, some parts of the integrated circuit 100 are not shown in FIGS. 6 and 7 and will not be discussed in the following (e.g., gate terminals and metallizations, possible passivation layers, etc.).

In FIGS. 6 and 7, the source terminal of the control switch S1 is designated by reference SS1, the source terminal of the control switch S1_0 is designated by reference SS1_0, and the source terminals of the high-side switches S2_j are designated by references SS2_j. Similarly, the drain terminal of the control switch S1 is designated by reference DS1, the drain terminal of the control switch S1_0 is designated by reference DS1_0, and the drain terminals of the high-side switches S2_j are designated by references DS2_j.

The source terminal SS1 of the control switch S1 is electrically connected via conductive vias that extend along direction Z and a source metallization 532 (e.g., including metal such as copper and/or gold) to a reference conductive layer (hereinafter referred to as layer GND, and for example including metal such as copper and/or gold), which extends in the semiconductor body 504. Furthermore, a drain metallization 530 (e.g., a redistribution layer including metal such as copper and/or gold) extends on the drains DS1, DS1_0 and DS2_j of the control switches S1, S1_0 and of the high-side switches S2_j, electrically contacting together these drains DS1, DS1_0 and DS2_j and operating as node 12 (common drain). The drain metallization 530 is electrically connected via further conductive vias to a conductive drain layer (e.g., including metal such as copper and/or gold) that extends in the semiconductor body 504, for example underneath the layer GND 506. Also, the source terminal SS1_0 of the control switch S1_0 is electrically connected via conductive vias that extend along direction Z to a respective source metallization 533 (e.g., including metal such as copper and/or gold). Additionally, the source terminals SS2_j of the high-side switches S2_j are electrically connected via conductive vias that extend along direction Z to respective source metallizations 534_j (e.g., including metal such as copper and/or gold).

Therefore, the source metallization 532 extends on the source terminal SS1 of the control switch S1 so as to set, also through conductive vias, the source terminal SS1 in electrical contact with the layer GND 506. Moreover, each source metallization 534_j extends on the source terminal SS2_j of a respective high-side switch S2_j so as to set, also through conductive vias, the respective source terminal SS2_j in electrical contact with a respective output pin/pad of the integrated circuit 100, which can be used for coupling to the anode terminal LDa_j of a respective laser diode LD_j once the laser lighting module 11 is assembled. Moreover, the common drain metallization 530 extends on the drain terminals DS1, DS1_0 and DS2_j of the control switches and of the high-side switches S2_j so as to set, also through conductive vias, all drain terminals in electrical contact with a respective output pin/pad of the integrated circuit 100, which can be used for coupling to the supply line 12 once the laser lighting module 11 is assembled. The source terminal SS1 of the control switch S1 and the source terminal SS1_0 of the control switch S1_0 may not be connected inside the package of the laser-driving device 101 (e.g., a SiP). The device 101 may be provided with dedicated pads for terminals SS1 and SS1_0, and these pads can be electrically connected outside the package of device 101 (e.g., using vias towards the ground layer of a printed circuit board where the cathode terminals of the laser diodes LD_j are soldered as well). Again, it is noted that gate metallizations and gate connections are not visible in FIGS. 6 and 7 for the sake of ease of illustration.

Optionally, electrical contact with the source, drain and/or gate terminals of the switches in the GaN integrated circuit 100 are obtained by appropriate I/O pads, designated in FIG. 7 by the following references: 540G1 indicating the pad for the gate terminal of the control switch S1, 540S1 indicating the pad for the source terminal SS1 of the control switch S1, 540D indicating the pad for the common drain terminal of the control switches and high-side switches, 540S1_0 indicating the pad for the source terminal SS1_0 of the control switch S1_0, 540G1_0 indicating the pad for the gate terminal of the control switch S1_0, 540S2_j indicating the pad for the source terminal SS2_j of a respective high-side switch S2_j, and 540G2_jindicating the pad for the gate terminal of a respective high-side switch S2_j.

Moreover, optionally, the source terminals SS2_j (and optionally also the source terminal SS1) are located in a position corresponding to a lateral surface of the semiconductor body 504, which joins together the first and second surfaces (parallel to plane XY and opposite along direction Z) of the semiconductor body 504, optionally at the top of the lateral surface of the semiconductor body 504. For instance, they face the (top) surface of the semiconductor body 504 at an edge of the latter that extends between the (top) surface and the lateral surface.

As exemplified in FIGS. 6 and 7, the source terminals SS2_j of the high-side switches S2_j as well as the source terminal SS1_0 of the control switch S1_0 are aligned with one another in a direction of alignment 540 parallel to the axis X, and the drains DS2_j of the high-side switches S2_j as well as the drain terminal DS1_0 of the control switch S1_0 are aligned with one another in a direction of alignment 542 parallel to the axis X. In addition, the source terminal SS1 and the drain terminal DS1 of the control switch S1 are aligned with one another in a respective direction perpendicular to the directions of alignment 540 and 542, and therefore parallel to the axis Y. Optionally, the control switch S1 has its respective drain terminal DS1 facing the drain terminals DS2_j and DS1_0 of the high-side switches S2_j and of the control switch S1_0, so as to simplify mutual electrical coupling of the latter by the drain metallization 530. The conductive channels of switches S1, S1_0 and S2_j may thus all extend (e.g., in a plane parallel to the first surface 504a of the semiconductor body 504) in the same direction, which is perpendicular to the direction of alignment 540, with the source terminal SS1 of the first control switch S1 being located at an opposite side of the semiconductor body 504 with respect to the source terminals SS1_0 and SS2_j of the second control switch S1_0 and of the high-side switches S2_j.

Optionally, the high-side switches S2_j have an area of extension, in the plane XY defined by the axes X and Y, that is designed on the basis of the RMS currents and/or the peak current that are to flow in the respective laser diodes LD_j. For instance, the area of extension of each high-side switch S2_j is such that a density of RMS current generated thereby is approximately 20 A/mm ² (value measured at approximately 25° C.) and, optionally, the respective on-state resistance RDSon is approximately 15 mΩ.

As exemplified in FIG. 7, the control switch S1 may be implemented as a set of transistors connected in parallel. In particular, switch S1 may comprise a number of transistors equal to the number of high-side transistors S2_j plus the other control transistor S1_0 (e.g., five transistors in the example considered herein, indicated by references S1m_1, S1m_2, S1m_3, S1m_4, and S1m_5, cumulatively also referred to as S1m_k). The transistors S1m_k, the high-side transistors S2_j and the transistor S1_0 may all have the same channel width W, e.g., equal to 500 μm. The transistors S1m_k may have a channel length of about 858 μm. The high-side transistors S2_j as well as the transistor S1_0 may have the same channel length of about 1857 μm. The semiconductor chip 100 may have a total dimension (in the XY plane) of about 3200μm measured along the X direction and 3104 μm measured along the Y direction.

As previously discussed, the high-side switches S2_j may be coupled to another integrated circuit 15 that includes the laser diodes LD_j. For instance, the integrated circuit 15 may consist of another semiconductor body, and the first surface 504a of semiconductor body 504 may face the surface of such another second semiconductor body.

Furthermore, according to one or more embodiments the solid body is formed by a printed circuit board (PCB) that includes one or more conductive paths (e.g., including metal such as copper), which extend on a first surface. In this case, the laser diodes LD_j, when coupled to the solid body, extend on the first surface and are in electrical contact with one of the aforesaid conductive paths, which electrically contacts also the conductive vias and operates as reference node GND. Moreover, a further conductive path between the conductive paths electrically contacts the drain metallization 530 and operates as first node or line 12. Also electrically coupled (for example, soldered on the first surface) to the solid body are the control circuit 18, the low-side switches S3_j, the resonant circuit LC and the regulator 16.

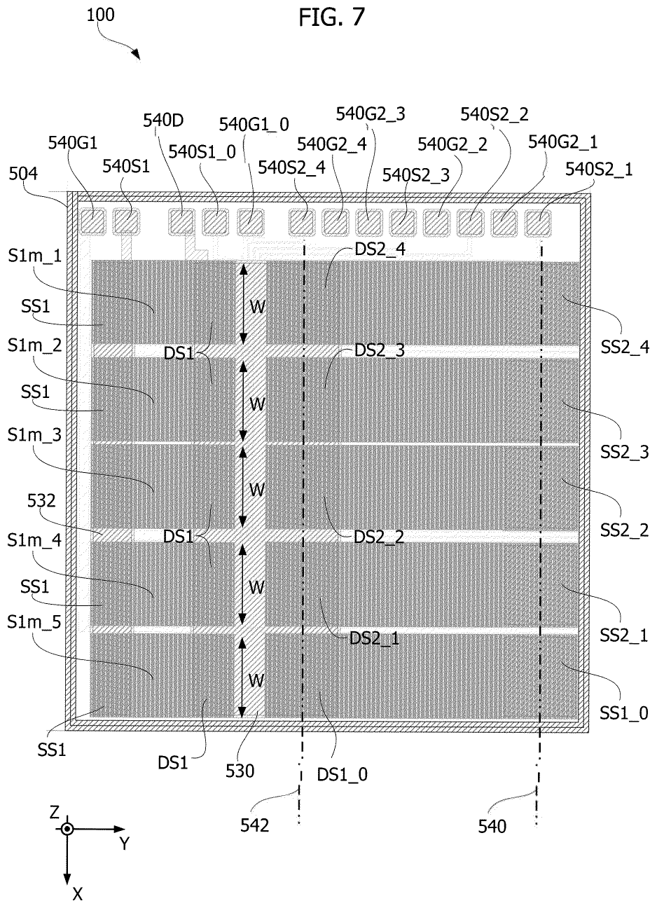

FIG. 8 is a time diagram exemplary of the switching behavior of a laser lighting module 11 according to one or more embodiments. In particular, in FIG. 8 are shown the four waveforms of the individual currents flowing through the four laser diodes LD_j during a laser firing phase (e.g., see again phase 252 of FIG. 2), which may be characterized by a rise time of about 380 ps and a current overshoot limited to about 5 A with respect to a target current of about 40 A.

FIG. 9 is an example of possible use of the laser lighting module 11 (more in particular, of the laser-driving device 101) in a LIDAR application. In particular, FIG. 9 shows a vehicle V (e.g., an automobile) comprising the LIDAR apparatus 1. The LIDAR apparatus 1 defines an emitter path EP and a receiver path RP.

The emitter path EP includes the laser lighting module 11, in turn including the laser diodes (here designated by LD) and the laser-driving device 101 that operates as driving system for the laser diodes LD, as discussed previously. The emitter path EP also includes a LIDAR mirror module 1002 (e.g., a MEMS mirror module), which receives actuation signals A from, and supplies sensing signals S to, a mirror driver (e.g., an ASIC) 1003, for instance with the capacity of lighting a surrounding environment with a vertical laser beam and carrying out in a horizontal direction a scan as desired in order to detect, in a reliable way, a pedestrian within a distance of a few meters.

The receiver path RP includes a photodiode module 1004 sensitive to the reflected signal produced as a result of a reflection of the radiation emitted by the emitter path EP on objects lit up by the radiation, and a receiver circuit 1005 coupled to the photodiode module 1004.

The LIDAR apparatus 1 further includes a controller 1006 (e.g., a multi-core microcontroller architecture, possibly including dedicated FPGA/LIDAR hardware accelerators 1006A) configured to: emit signals for triggering and setting the power of the TPS laser to the laser-driving device 101 for laser lighting; exchange driving information DI with the mirror driver 1003 of the mirror module 1002; and receive raw data RD from, and send information of trigger and gain setting TGS to, the receiver circuit 1005 coupled to the photodiode module 1004.

It may be noted that, except for the laser lighting module 11 and more in particular the laser-driving device 101, the architecture illustrated in FIG. 9 is conventional in the art, which renders a more detailed description thereof superfluous. This applies, for example, with reference to the co-ordination of operation of the LIDAR apparatus 1 with operation of the vehicle V (for example, in view of the configuration data received in the controller 1006 and of cloud information of status points as issued by the controller 1006).

Without prejudice to the underlying principles, the details and embodiments may vary, even significantly, with respect to what has been described by way of example only, without departing from the extent of protection.

The extent of protection is determined by the annexed claims.

What is claimed is:

1. A driver circuit couplable to a plurality of laser diodes, the driver circuit comprising:
a semiconductor body having a first surface;
a first control switch having a drain terminal electrically coupled to a drain metallization and having a source terminal electrically coupled to a first source metallization, wherein the drain metallization is configured to be electrically coupled to a power supply line and the first source metallization is configured to be coupled to cathode terminals of the laser diodes and to a reference node;
a second control switch having a drain terminal electrically coupled to the drain metallization and having a source terminal electrically coupled to a second source metallization, wherein the second source metallization is configured to be coupled to the cathode terminals of the laser diodes and to the reference node; and
a plurality of high-side switches, each high-side switch having a respective drain terminal electrically coupled to the drain metallization and having a respective source terminal electrically coupled to a respective third source metallization, wherein each third source metallization is coupled to a respective drive output node for driving an anode terminal of a respective laser diode of the plurality of laser diodes;
wherein the drain metallization, the first source metallization, the second source metallization and the third source metallizations face the first surface of the semiconductor body, which is also configured to face the laser diodes; and
wherein the second source metallization and the third source metallizations are aligned with one another in a direction of alignment and are superimposed, orthogonally to the direction of alignment, to the respective source terminals of the second control switch and of the high-side switches.

2. The driver circuit of claim 1, wherein a conductive channel of the first control switch is larger than a conductive channel of the second control switch, whereby an on-state resistance of the first control switch is smaller than an on-state resistance of the second control switch.

3. The driver circuit of claim 1, wherein:
the first control switch, the second control switch and the high-side switches have respective conductive channels that extend in a direction perpendicular to the direction of alignment and parallel to the first surface; and
the source terminal of the first control switch is located at an opposite side of the semiconductor body with respect to the source terminals of the second control switch and of the high-side switches.

4. The driver circuit of claim 1, wherein the first control switch has a conductive channel having a width equal to a sum of the widths of the conductive channels of the second control switch and of the high-side switches.

5. The driver circuit of claim 1, wherein the first control switch comprises a plurality of first control transistors electrically connected in parallel, wherein a number of the first control transistors is equal to a number of the second control switch plus the high-side switches.

6. The driver circuit of claim 5, wherein each of the first control transistors, each of the high-side switches and the second control switch have respective conductive channels having all a same width.

7. A laser-driving device, comprising:
a driver circuit couplable to a plurality of laser diodes, the driver circuit comprising:
a semiconductor body having a first surface;
a first control switch having a drain terminal electrically coupled to a drain metallization and having a source terminal electrically coupled to a first source metallization, wherein the drain metallization is configured to be electrically coupled to a power supply line and the first source metallization is configured to be coupled to cathode terminals of the laser diodes and to a reference node;
a second control switch having a drain terminal electrically coupled to the drain metallization and having a source terminal electrically coupled to a second source metallization, wherein the second source metallization is configured to be coupled to the cathode terminals of the laser diodes and to the reference node; and
a plurality of high-side switches, each high-side switch having a respective drain terminal electrically coupled to the drain metallization and having a respective source terminal electrically coupled to a respective third source metallization, wherein each third source metallization is coupled to a respective drive output node for driving an anode terminal of a respective laser diode of the plurality of laser diodes;
wherein the drain metallization, the first source metallization, the second source metallization and the third source metallizations face the first surface of the semiconductor body, which is also configured to face the laser diodes; and
wherein the second source metallization and the third source metallizations are aligned with one another in a direction of alignment and are superimposed, orthogonally to the direction of alignment, to the respective source terminals of the second control switch and of the high-side switches; and
a control circuit configured to drive the first control switch, the second control switch, and the high-side switches to cyclically generate pulses for activating the laser diodes, the control circuit configured to:
sense a voltage across a capacitor of an external resonant circuit;
in response to the sensed voltage reaching a first threshold value, close the first control switch and the second control switch, thereby enabling the external resonant circuit to oscillate with a current that flows in an inductor of the external resonant circuit and is split between the first control switch and the second control switch;
in response to the current flowing in the inductor of the external resonant circuit reaching a second threshold value, open the first control switch and keep closed the second control switch for a first time interval, whereby the current flows entirely through the second control switch;
in response to expiration of the first time interval, open the second control switch and close a first selected high-side switch for a second time interval, whereby the current flows entirely through the first selected high-side switch and is output via a respective first drive output node; and
in response to expiration of the second time interval, open the first selected high-side switch.

8. The laser-driving device of claim 7, wherein the control circuit is further configured to:
in response to expiration of the second time interval, close a second selected high-side switch that is adjacent to the first selected high-side switch for a third time interval, whereby the current is switched from the first selected high-side switch to the second selected high-side switch and flows entirely through the second selected high-side switch and is output via a respective second drive output node; and
in response to expiration of the third time interval, open the second selected high-side switch.

9. The laser-driving device of claim 7, wherein the control circuit is further configured to:
in response to expiration of the second time interval, close the second control switch for a third time interval, whereby the current is switched from the first selected high-side switch to the second control switch and flows entirely through the second control switch;
in response to expiration of the third time interval, open the second control switch and close a second selected high-side switch for a fourth time interval, whereby the current flows entirely through the second selected high-side switch and is output via a respective second drive output node; and
in response to expiration of the fourth time interval, open the second selected high-side switch.

10. The laser-driving device of claim 7, wherein the control circuit comprises a plurality of low-side switches configured for coupling to respective ones of the high-side switches, wherein each low-side switch is configured to be coupled between a respective one of the drive output nodes and the reference node, and wherein the control circuit is further configured to close each of the low-side switches when the respective high-side switch is open.

11. The laser-driving device of claim 7, wherein a conductive channel of the first control switch is larger than a conductive channel of the second control switch, whereby an on-state resistance of the first control switch is smaller than an on-state resistance of the second control switch.

12. The laser-driving device of claim 7, wherein:
the first control switch, the second control switch and the high-side switches have respective conductive channels that extend in a direction perpendicular to the direction of alignment and parallel to the first surface; and
the source terminal of the first control switch is located at an opposite side of the semiconductor body with respect to the source terminals of the second control switch and of the high-side switches.

13. The laser-driving device of claim 7, wherein the first control switch has a conductive channel having a width equal to a sum of the widths of the conductive channels of the second control switch and of the high-side switches.

14. The laser-driving device of claim 7, wherein the first control switch comprises a plurality of first control transistors electrically connected in parallel, wherein a number of the first control transistors is equal to a number of the second control switch plus the high-side switches.

15. The laser-driving device of claim 14, wherein each of the first control transistors, each of the high-side switches and the second control switch have respective conductive channels having all a same width.

16. A laser lighting module, comprising:
the laser-driving device according to claim 7;
a resonant circuit including an inductor and a capacitor having an intermediate node between them, the resonant circuit being coupled between the power supply line and the reference node;
a charging circuitry coupled between a supply node and the intermediate node of the resonant circuit for charging the capacitor of the resonant circuit; and
a plurality of laser diodes, wherein each of the laser diodes has an anode terminal electrically coupled to a respective one of the drive output nodes and a cathode terminal electrically coupled to the reference node.

17. The laser lighting module of claim 16, wherein the control circuit comprises a plurality of low-side switches configured for coupling to respective ones of the high-side switches, wherein each low-side switch is configured to be coupled between a respective one of the drive output nodes and the reference node, and wherein the control circuit is further configured to close each of the low-side switches when the respective high-side switch is open.

18. A light detection and ranging (LIDAR) apparatus, comprising:
a laser light emitter path comprising:
a LIDAR mirror module; and
a laser lighting module comprising:
the laser-driving device according to claim 7;
a resonant circuit including an inductor and a capacitor having an intermediate node between them, the resonant circuit being coupled between the power supply line and the reference node;
a charging circuitry coupled between a supply node and the intermediate node of the resonant circuit for charging the capacitor of the resonant circuit; and
a plurality of laser diodes, wherein each of the laser diodes has an anode terminal electrically coupled to a respective one of the drive output nodes and a cathode terminal electrically coupled to the reference node;
a laser light receiver path comprising a photodiode module and a receiver circuit coupled to the photodiode module; and
a controller circuit configured to:
emit driving signals for the LIDAR mirror module and the laser lighting module; and
receive raw data from the receiver circuit coupled to the photodiode module.

19. A method of operating a laser-driving device comprising a driver circuit couplable to a plurality of laser diodes, the driver circuit comprising a semiconductor body having a first surface, a first control switch having a drain terminal electrically coupled to a drain metallization and having a source terminal electrically coupled to a first source metallization, wherein the drain metallization is configured to be electrically coupled to a power supply line and the first source metallization is configured to be coupled to cathode terminals of the laser diodes and to a reference node, a second control switch having a drain terminal electrically coupled to the drain metallization and having a source terminal electrically coupled to a second source metallization, wherein the second source metallization is configured to be coupled to the cathode terminals of the laser diodes and to the reference node, and a plurality of high-side switches, each high-side switch having a respective drain terminal electrically coupled to the drain metallization and having a respective source terminal electrically coupled to a respective third source metallization, wherein each third source metallization is coupled to a respective drive output node for driving an anode terminal of a respective laser diode of the plurality of laser diodes, the drain metallization, the first source metallization, the second source metallization and the third source metallizations facing the first surface of the semiconductor body, which is also configured to face the laser diodes, and the second source metallization and the third source metallizations being aligned with one another in a direction of alignment and are superimposed, orthogonally to the direction of alignment, to the respective source terminals of the second control switch and of the high-side switches, and a control circuit configured to drive the first control switch, the second control switch, and the high-side switches to cyclically generate pulses for activating the laser diodes, the method comprising:
sensing a voltage across a capacitor of an external resonant circuit;
in response to the sensed voltage reaching a first threshold value, closing the first control switch and the second control switch, thereby enabling the resonant circuit to oscillate with a current that flows in an inductor of the resonant circuit and is split between the first control switch and the second control switch;
in response to the current flowing in the inductor of the resonant circuit reaching a second threshold value, opening the first control switch and keeping closed the second control switch for a first time interval, whereby the current flows entirely through the second control switch;
in response to expiration of the first time interval, opening the second control switch and closing a first selected high-side switch for a second time interval, whereby the current lows entirely through the first selected high-side switch and is output via a respective first drive output node; and
in response to expiration of the second time interval, opening the first selected high-side switch.

20. A method of operating a laser lighting module comprising a laser-driving device comprising a driver circuit couplable to a plurality of laser diodes, the driver circuit comprising a semiconductor body having a first surface, a first control switch having a drain terminal electrically coupled to a drain metallization and having a source terminal electrically coupled to a first source metallization, wherein the drain metallization is configured to be electrically coupled to a power supply line and the first source metallization is configured to be coupled to cathode terminals of the laser diodes and to a reference node, a second control switch having a drain terminal electrically coupled to the drain metallization and having a source terminal electrically coupled to a second source metallization, wherein the second source metallization is configured to be coupled to the cathode terminals of the laser diodes and to the reference node, and a plurality of high-side switches, each high-side switch having a respective drain terminal electrically coupled to the drain metallization and having a respective source terminal electrically coupled to a respective third source metallization, wherein each third source metallization is coupled to a respective drive output node for driving an anode terminal of a respective laser diode of the plurality of laser diodes, the drain metallization, the first source metallization, the second source metallization and the third source metallizations facing the first surface of the semiconductor body, which is also configured to face the laser diodes, and the second source metallization and the third source metallizations being aligned with one another in a direction of alignment and are superimposed, orthogonally to the direction of alignment, to the respective source terminals of the second control switch and of the high-side switches, and a control circuit configured to drive the first control switch, the second control switch, and the high-side switches to cyclically generate pulses for activating the laser diodes, the laser lighting module further comprising a resonant circuit including an inductor and a capacitor having an intermediate node between them, the resonant circuit being coupled between the power supply line and the reference node, a charging circuitry coupled between a supply node and the intermediate node of the resonant circuit for charging the capacitor of the resonant circuit, and a plurality of laser diodes, wherein each of the laser diodes has an anode terminal electrically coupled to a respective one of the drive output nodes and a cathode terminal electrically coupled to the reference node, the method comprising:
initially opening the first control switch and the second control switch to charge the capacitor via the charging circuitry, and
operating the laser-driving device, the operating comprising:
sensing a voltage across a capacitor of an external resonant circuit;
in response to the sensed voltage reaching a first threshold value, closing the first control switch and the second control switch, thereby enabling the resonant circuit to oscillate with a current that flows in an inductor of the resonant circuit and is split between the first control switch and the second control switch;
in response to the current flowing in the inductor of the resonant circuit reaching a second threshold value, opening the first control switch and keeping closed the second control switch for a first time interval, whereby the current flows entirely through the second control switch;
in response to expiration of the first time interval, opening the second control switch and closing a first selected high-side switch for a second time interval, whereby the current lows entirely through the first selected high-side switch and is output via a respective first drive output node; and
in response to expiration of the second time interval, opening the first selected high-side switch.
